(19) United States
(12) Patent Application Publication
(10) Pub. No.: US 2026/0089838 A1
(43) Pub. Date: Mar. 26, 2026

(54) CERAMIC SUBSTRATE AND ELECTRONIC COMPONENT

(71) Applicant: Murata Manufacturing Co., Ltd., Nagaokakyo-shi (JP)

(72) Inventor: Hiromasa YABUKI, Nagaokakyo-shi (JP)

(21) Appl. No.: 19/407,503

(22) Filed: Dec. 3, 2025

Related U.S. Application Data
(63) Continuation of application No. PCT/JP2024/017566, filed on May 13, 2024.

(30) Foreign Application Priority Data
Aug. 23, 2023 (JP) 2023-135597

(51) Int. Cl. H05K 1/03; H05K 1/16

(52) U.S. Cl. CPC H05K 1/0306; H05K 1/162; H05K 1/165

(57) ABSTRACT

A ceramic substrate that includes: a base body including a ceramic layer; at least one inner conductor in the base body; a terminal electrode including a first electrode in contact with an outer surface of the base body and a second electrode covering a surface of the first electrode; and an insulating layer covering at least a portion of an outer periphery of the first electrode, the ceramic substrate including a section where the first electrode, the insulating layer, and the second electrode overlap in a thickness direction, the first electrode having a non-conductive component content of from 3% by weight to 40% by weight, the second electrode having a non-conductive component content of from 0% by weight to 10% by weight, and the non-conductive component content of the first electrode being equal to or greater than the non-conductive component content of the second electrode.

### CROSS REFERENCE TO RELATED APPLICATIONS

The present application is a continuation of International application No. PCT/JP2024/017566, filed May 13, 2024, which claims priority to Japanese Patent Application No. 2023-135597, filed Aug. 23, 2023, the entire contents of each of which are incorporated herein by reference.

### TECHNICAL FIELD

The present disclosure relates to ceramic substrates and electronic components.

### BACKGROUND ART

JP 2005-209881 A (“Patent Literature 1”) discloses a multilayer ceramic substrate including a plurality of ceramic layers and electrode patterns. The multilayer ceramic substrate has a terminal electrode and an insulating layer on its outer surface. The terminal electrode includes a base layer and an upper layer formed of the electrode patterns. The insulating layer covers at least a portion of the outer periphery of the base layer and the ceramic layers, and also the upper layer covers at least a portion of the insulating layer, so that the insulating layer is interposed between the upper layer and the base layer.

### SUMMARY OF THE DISCLOSURE

In the multilayer ceramic substrate in Patent Literature 1, the base layer and the upper layer in the terminal electrode adhere to the insulating layer. When tensile stress due to, for example, thermal stress is applied to the terminal electrode, the stress is likely to concentrate on the outer periphery of the terminal electrode and may cause a crack in the insulating layer just below the outer periphery of the upper layer. A crack forming from an edge of the upper layer into the insulating layer is expected to be stopped by the base layer. However, the base layer is thin just below the insulating layer and may not sufficiently stop the growth of the crack. Thus, the crack may continue to grow and reach an electrode in the multilayer substrate, potentially disrupting the conduction of the electrode in the multilayer substrate.

The present disclosure has been made to solve the above-described problem and aims to provide a ceramic substrate with reliable electrical conductivity between a terminal electrode and an inner conductor. The present disclosure also aims to provide an electronic component including the ceramic substrate.

The ceramic substrate of the present disclosure includes: a base body including a ceramic layer; at least one inner conductor in the base body; a terminal electrode including a first electrode in contact with an outer surface of the base body and a second electrode covering a surface of the first electrode, the terminal electrode being electrically connected to the at least one inner conductor; and an insulating layer covering at least a portion of an outer periphery of the first electrode and a portion of the outer surface of the base body, the ceramic substrate including a section where the first electrode, the insulating layer, and the second electrode overlap in this order from the outer surface of the base body in a thickness direction orthogonal to the outer surface of the base body, the first electrode having a non-conductive component content of from 3% by weight to 40% by weight, the second electrode having a non-conductive component content of from 0% by weight to 10% by weight, and the non-conductive component content of the first electrode being equal to or greater than the non-conductive component content of the second electrode.

The electronic component of the present disclosure includes the ceramic substrate of the present disclosure.

The present disclosure can provide a ceramic substrate with reliable electrical conductivity between a terminal electrode and an inner conductor. The present disclosure can also provide an electronic component including the ceramic substrate.

### BRIEF DESCRIPTION OF THE DRAWINGS

FIG. 1 is a schematic cross-sectional view showing an example of the ceramic substrate of the present disclosure.

FIG. 2 is a schematic plan view showing examples of a terminal electrode and an insulating layer.

FIG. 3 is a schematic cross-sectional view showing how a crack forms in the ceramic substrate of the present disclosure.

FIG. 4 is a schematic cross-sectional view showing how a crack forms in a ceramic substrate of a comparative example in which a second electrode strongly adheres to an insulating layer.

FIG. 5 is a schematic cross-sectional view showing how a crack forms in a ceramic substrate of a comparative example in which a first electrode weakly adheres to a base body.

FIG. 6 is a schematic cross-sectional view showing how a crack forms in a ceramic substrate of a comparative example in which a first electrode itself has a low strength.

FIG. 7 is a schematic cross-sectional view showing a process of forming a first electrically conductive paste layer to be fired into a first electrode.

FIG. 8 is a schematic plan view showing the process of forming a first electrically conductive paste layer to be fired into a first electrode.

FIG. 9 is a schematic cross-sectional view showing a process of forming an insulating paste layer to be fired into an insulating layer.

FIG. 10 is a schematic plan view showing the process of forming an insulating paste layer to be fired into an insulating layer.

FIG. 11 is a schematic cross-sectional view showing a process of forming a second electrically conductive paste layer to be fired into a second electrode.

FIG. 12 is a schematic plan view showing the process of forming a second electrically conductive paste layer to be fired into a second electrode.

FIG. 13 is a schematic cross-sectional view showing a first modification example of the ceramic substrate.

FIG. 14 is a schematic cross-sectional view showing a second modification example of the ceramic substrate.

FIG. 15 is a schematic plan view showing the second modification example of the ceramic substrate.

FIG. 16 is a schematic cross-sectional view showing a third modification example of the ceramic substrate.

FIG. 17 is a schematic plan view showing the third modification example of the ceramic substrate.

FIG. 18 is a schematic perspective view showing an example of the electronic component of the present disclosure.

FIG. 19 is a schematic perspective view showing an input/output terminal and a ground terminal in an example of the electronic component of the present disclosure.

FIG. 20 is an exploded schematic perspective view showing an example of the electronic component of the present disclosure.

### DESCRIPTION OF THE PREFERRED EMBODIMENTS

Hereinafter, the ceramic substrate of the present disclosure will be described.

The present disclosure is not limited to the following preferred embodiments and may be suitably modified without departing from the gist of the present disclosure. Combinations of two or more preferred embodiments described below are also within the scope of the present disclosure.

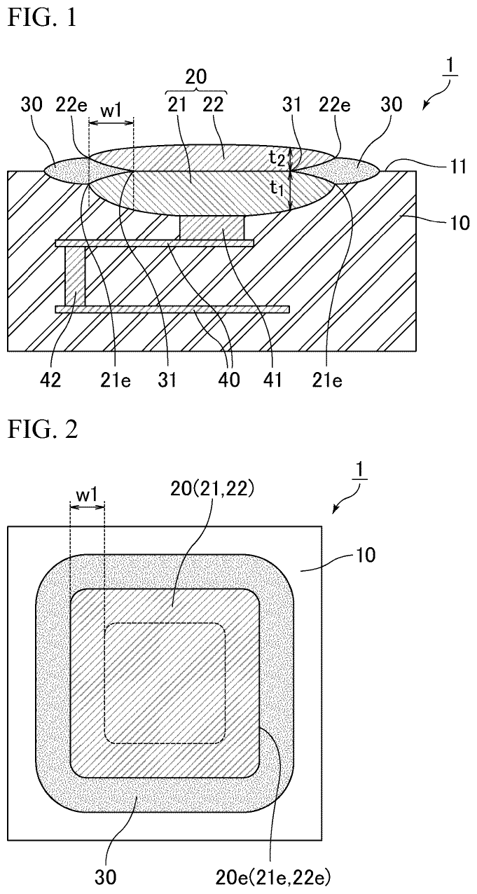

FIG. 1 is a schematic cross-sectional view showing an example of the ceramic substrate of the present disclosure.

A ceramic substrate 1 includes a base body 10 including a ceramic layer, at least one inner conductor 40 in the base body 10, a terminal electrode 20 on an outer surface of the base body 10, and an insulating layer 30 on the outer surface of the base body 10.

The base body 10 includes a ceramic layer. The base body 10 may be a multilayer ceramic substrate including a plurality of ceramic layers.

The material of the base body 10 is not limited and may be, for example, a low-temperature co-fired ceramic (LTCC) material.

The term “low-temperature co-fired ceramic material” refers to a ceramic material that can be sintered at a temperature of 1000° C. or lower and can also be co-fired with a metal with low resistivity such as Au, Ag, or Cu. Specific examples of the low-temperature co-fired ceramic material include a glass-composite low-temperature co-fired ceramic material which is a mixture of borosilicate glass with ceramic powder such as alumina, zirconia, magnesia, spinel, or forsterite powder, a crystallized glass-based low-temperature co-fired ceramic material prepared using ZnO—MgO—Al₂O₃—SiO₂-based crystallized glass, and a non-glass-based low-temperature co-fired ceramic material prepared using ceramic powder such as BaO—Al₂O₃—SiO₂-based ceramic powder or Al₂O₃—CaO—SiO₂—MgO—B₂O₃-based ceramic powder.

The base body 10 may contain glass. The base body 10 may be a sintered glass ceramic. Non-limiting examples of the glass include borosilicate glass and crystallized glass.

Examples of the material of the base body 10 include a glass ceramic composition that contains (1) a first ceramic containing at least one of MgAl₂O₄ and Mg₂SiO₄, (2) a second ceramic containing BaO, RE₂O₃ (RE represents a rare earth element), and TiO₂, (3) glass containing 44.0 to 69.0% by weight of RO (R represents at least one alkaline-earth metal selected from Ba, Ca, and Sr), 14.2 to 30.0% by weight of SiO₂, 10.0 to 20.0% by weight of B₂O₃, 0.5 to 4.0% by weight of Al₂O₃, 0.3 to 7.5% by weight of Li₂O, and 0.1 to 5.5% by weight of MgO, and (4) MnO, wherein the amount of the first ceramic is 47.55 to 69.32% by weight, the amount of the glass is 6 to 20% by weight, the amount of the MnO is 7.5 to 18.5% by weight, and the second ceramic contains 0.38 to 1.43% by weight of BaO, 1.33 to 9.5% by weight of RE₂O₃, and 0.95 to 6.75% by weight of TiO₂.

The glass ceramic composition may contain 0.23% by weight or less of CuO.

The glass ceramic composition may contain 3 to 20% by weight of a third ceramic containing at least one of Mg₂Al₄Si₅O₁₈ and BaAl₂Si₂O₈ and may further contain 0.3% by weight or less of CuO in addition to the third ceramic.

Examples of the material of the base body 10 also include a glass ceramic that contains an aggregate and glass containing Si, B, Al, and Zn, wherein the amount of the glass is from 45% by weight to 80% by weight, and the aggregate has a SiO₂ content of from 20% by weight to 50% by weight, an Al₂O₃ content of 20% by weight or less, and a ZnO content of 10% by weight or less, relative to the weight of the glass ceramic.

The glass ceramic may contain SiO₂, ZnAl₂O₄, and Al₂O₃ as crystalline phases.

The glass in the glass ceramic may have a SiO₂ content of from 15% by weight to 65% by weight, a B₂O₃ content of from 11% by weight to 30% by weight, a weight ratio of SiO₂ to B₂O₃ (SiO₂/B₂O₃) of 1.21 or greater, and a weight ratio of Al₂O₃ to ZnO (Al₂O₃/ZnO) of from 0.75 to 1.64.

The glass in the glass ceramic may be crystallized glass, and the glass ceramic may contain ZnAl₂O₄ which is a crystalline phase precipitated from the glass.

The glass in the glass ceramic may contain Li₂O as a sub component and may have a Li₂O content of 1.0% by weight or less.

The glass in the glass ceramic may have a crystallization temperature of 1000° C. or lower.

The glass ceramic may have a relative dielectric constant of 5 or less.

The Si, B, Al, and Zn contents of the glass ceramic may be specified without distinguishing between the glass and the aggregate. Examples of the material with Si, B, Al, and Zn contents specified without distinguishing between the glass and the aggregate include a glass ceramic that contains Si, B, Al, and Zn and has a SiO₂ content of from 52.00% by weight to 71.58% by weight, a B₂O₃ content of from 6.30% by weight to 21.00% by weight, an Al₂O₃ content of from 7.63% by weight to 22.00% by weight, a ZnO content of from 5.04% by weight to 17.00% by weight, and a Li₂O content of 0.55% by weight or less. Table 1 shows the percentages of elements in some glass ceramics.

TABLE 1

Percentage of element in glass ceramic

| Ceramic | SiO₂ | B₂O₃ | Al₂O₃ | ZnO | Li₂O |
|---|---|---|---|---|---|
| No. | [wt %] | [wt %] | [wt %] | [wt %] | [wt %] |
| L1 | 67.52 | 15.04 | 8.72 | 8.72 | 0.00 |
| L2 | 71.58 | 13.16 | 7.63 | 7.63 | 0.00 |
| L3 | 66.58 | 13.16 | 12.63 | 7.63 | 0.00 |
| L4 | 65.09 | 12.69 | 12.36 | 9.86 | 0.00 |
| L5 | 68.61 | 12.09 | 12.09 | 7.08 | 0.13 |
| L6 | 59.00 | 10.50 | 16.50 | 14.00 | 0.00 |
| L7 | 52.00 | 9.00 | 22.00 | 17.00 | 0.00 |
| L8 | 59.75 | 7.70 | 21.00 | 11.00 | 0.55 |
| L9 | 70.25 | 6.30 | 14.00 | 9.00 | 0.45 |
| L10 | 60.00 | 21.00 | 12.21 | 6.79 | 0.00 |
| L11 | 70.50 | 14.00 | 10.46 | 5.04 | 0.00 |

The glass ceramic preferably has a SiO₂ content of 60% by weight or more, a B₂O₃ content of 15% by weight or less, an Al₂O₃ content of 15% by weight or less, and a ZnO content of 12% by weight or less. Such a glass ceramic can have a relative dielectric constant of 5 or less or even 4.5 or less.

The base body 10 includes at least one inner conductor 40 therein, and the at least one inner conductor 40 is electrically connected to the terminal electrode 20. The at least one inner conductor 40 may have any structure that is electrically connected to the terminal electrode 20. One inner conductor 40 or a plurality of inner conductors 40 may be present in the base body 10. The at least one inner conductor 40 may contain any material and may contain, for example, Cu or Ag as a conductive component.

As shown in FIG. 1, the at least one inner conductor 40 may include a via conductor 41 connected to the first electrode 21. In this case, the at least one inner conductor 40 is electrically connected to the terminal electrode 20 through the via conductor 41.

As shown in FIG. 1, the at least one inner conductor 40 may include a plurality of stacked conductor patterns which are connected to each other. In this case, the at least one inner conductor 40 may include a via conductor 42 that connects the plurality of stacked inner conductors, in addition to the via conductor 41 for the connection to the first electrode 21. As described below, the ceramic substrate 1 may become an electronic component when the inner conductors 40 in the base body 10 serve as an inductance element and a capacitance element.

The terminal electrode 20 is disposed on the outer surface of the base body 10. The terminal electrode 20 includes the first electrode 21 in contact with the outer surface of the base body 10 and the second electrode 22 covering a surface of the first electrode 21. The first electrode 21 and the second electrode 22 will be described in detail below.

The insulating layer 30 is disposed on the outer surface of the base body 10. The insulating layer 30 covers at least a portion of an outer periphery 21e of the first electrode 21 and a portion of the outer surface of the base body 10. In the cross section in FIG. 1, the insulating layer 30 covers the outer peripheries 21e on both sides of the first electrode 21 and a portion of the outer surface of the base body 10. As shown in FIG. 1, the insulating layer 30 may cover the entire part not covered by the second electrode 22 in the outer surface of the first electrode 21. In other words, the entire outer surface of the first electrode 21 may be covered by the second electrode 22 and the insulating layer 30.

The ceramic substrate includes a section (the section indicated by double-headed arrow w1 in FIG. 1 and FIG. 2) where the first electrode 21, the insulating layer 30, and the second electrode 22 overlap in this order from the outer surface of the base body 10 in a thickness direction (the vertical direction in FIG. 1) orthogonal to the outer surface of the base body 10. In FIG. 1, the first electrode 21, the insulating layer 30, and the second electrode 22 overlap in this order from the outer surface of the base body 10 in the entire portion where the insulating layer 30 covers the first electrode 21. At the section where the first electrode 21, the insulating layer 30, and the second electrode 22 overlap in this order, the insulating layer 30 is interposed between the first electrode 21 and the second electrode 22.

In a cross-sectional view of the section where the first electrode 21, the insulating layer 30, and the second electrode 22 overlap in this order from the outer surface of the base body 10 in the thickness direction, an inner edge 31 of the insulating layer 30 is in contact with the first electrode 21 and the second electrode 22. Namely, the inner edge 31 of the insulating layer 30 is a point where the three members, specifically, the first electrode 21, the second electrode 22, and the insulating layer 30, are in contact with each other.

FIG. 2 is a schematic plan view showing examples of a terminal electrode and an insulating layer.

The second electrode 22 is present on the first electrode 21. Although only the second electrode 22 in the terminal electrode 20 is visible in the plan view in FIG. 2, the first electrode 21 is present beneath the second electrode 22.

As shown in FIG. 2, the insulating layer 30 may be present on the entire outer periphery 20e of the terminal electrode 20. In other words, the insulating layer 30 may cover the entire outer periphery 21e of the first electrode 21. The section where the first electrode 21, the insulating layer 30, and the second electrode 22 overlap in this order from the outer surface of the base body 10 in a thickness direction orthogonal to the outer surface of the base body 10, the insulating layer 30 may be present on the entire outer periphery 20e of the terminal electrode 20.

The material of the insulating layer 30 is not limited as long as it is a layer of an insulating material. For example, a ceramic insulating layer may be usable. Examples of the ceramic insulating layer include a ceramic insulating layer containing the low-temperature co-fired ceramic material described above. Examples also include a ceramic insulating layer prepared by adding an appropriate amount of alumina (Al₂O₃) powder to the low-temperature co-fired ceramic material and mixing them to give a mixed raw material powder, dispersing the powder in an organic vehicle and kneading to give a ceramic paste for forming a ceramic insulating layer, and applying and drying the ceramic paste.

The insulating layer 30 may contain glass. The insulating layer 30 may be a sintered glass ceramic. Non-limiting examples of the glass include borosilicate glass and crystallized glass. The insulating layer 30 may contain the same glass as that contained in the base body 10.

The insulating layer 30 and the base body 10 may contain the same main component. The insulating layer 30 and the base body 10 may have the same composition.

The first electrode 21 and the second electrode 22 will be described below.

The first electrode 21 has a non-conductive component content of from 3% by weight to 40% by weight.

The second electrode 22 has a non-conductive component content of from 0% by weight to 10% by weight.

The non-conductive component content of the first electrode 21 is equal to or greater than the non-conductive component content of the second electrode 22.

In the present disclosure, the term “non-conductive component content” refers to the amount of the constituent components of an electrode excluding Cu and Ag which are conductive components. The non-conductive component content of an electrode can be determined by observing a cross section of the electrode by scanning electron microscope-energy dispersive X-ray spectroscopy (SEM-EDX). Specifically, the conductive component content is calculated by the following method.

First, the weight percentages of elements in a cross section of the electrode are measured by elemental analysis through SEM-EDX. The total of the weight percentages of the elements detected by SEM-EDX excluding C and O is determined to be a total weight (100% by weight).

The ratio of the sum of the weight percentages of the Cu element and the Ag element relative to the total weight is determined as a conductive component content. The non-conductive component content is calculated by subtracting the weight percentages of the Cu element and the Ag element from the total weight.

The following will describe the effect due to the non-conductive component contents of the first electrode 21 and the second electrode 22 within the above ranges.

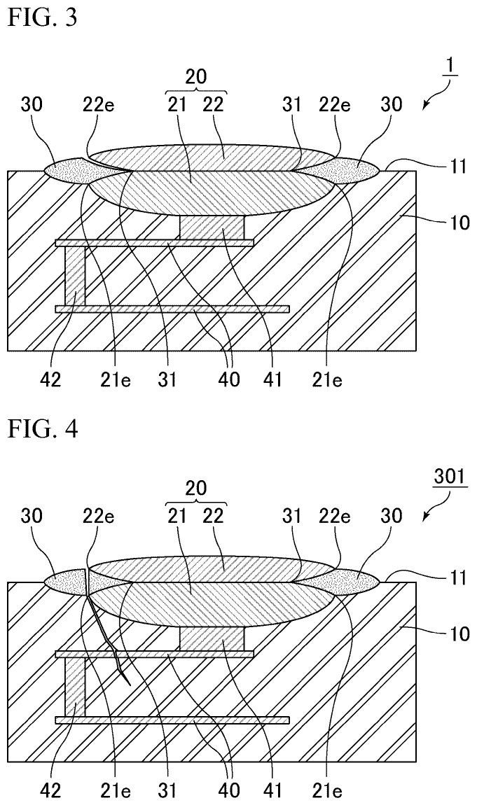

FIG. 3 is a schematic cross-sectional view showing how a crack forms in the ceramic substrate of the present disclosure.

FIG. 3 illustrates a crack between the second electrode 22 and the insulating layer 30.

The second electrode 22 which has a non-conductive component content of from 0% by weight to 10% by weight weakly adheres to the insulating layer 30. In the case where the ceramic substrate 1 is subjected to an electrode delamination stress, the second electrode 22 is easily detached from the insulating layer 30, so that a crack is likely to form along the boundary between the second electrode 22 and the insulating layer 30. When a crack grows and reaches the inner edge 31 of the insulating layer 30, since the inner edge 31 is highly stress resistant because of the strong adhesion between the first electrode 21 and the second electrode 22, the crack stops growing at the inner edge 31 of the insulating layer 30. This suppresses occurrence of a crack which fractures the at least one inner conductor 40 in the base body 10, thereby achieving reliable electrical conductivity from the terminal electrode 20 to the at least one inner conductor 40.

Moreover, a crack along the boundary between the second electrode 22 and the insulating layer 30 reduces the stress applied to the terminal electrode 20 and the insulating layer 30 to improve thermal stress resistance of the terminal electrode 20 and the insulating layer 30.

The first electrode 21 which has a non-conductive component content of 3% by weight or more can strongly adhere to the base body 10, so that the growth of a crack between the first electrode 21 and the base body 10 is inhibited. This prevents detachment of the first electrode 21 from the base body 10, thereby achieving reliable electrical conductivity from the terminal electrode 20 to the at least one inner conductor 40.

The first electrode 21 which has a non-conductive component content of 40% by weight or less itself has a high strength. Therefore, when a crack grows and reaches the inner edge 31 of the insulating layer 30, the crack is prevented from growing into the first electrode 21, thereby achieving reliable electrical conductivity from the terminal electrode 20 to the at least one inner conductor 40.

The non-conductive component content of the first electrode 21 is equal to or greater than the non-conductive component content of the second electrode 22. Thus, a crack is likely to occur along the boundary between the second electrode 22 and the insulating layer 30. When a crack grows and reaches the inner edge 31 of the insulating layer 30, since the inner edge 31 is highly stress resistant because of the strong adhesion between the first electrode 21 and the second electrode 22, the crack stops growing at the inner edge 31 of the insulating layer 30. This suppresses occurrence of a crack which fractures the at least one inner conductor 40 in the base body 10, thereby achieving reliable electrical conductivity from the terminal electrode 20 to the at least one inner conductor 40.

FIG. 4 is a schematic cross-sectional view showing how a crack forms in a ceramic substrate of a comparative example in which a second electrode strongly adheres to an insulating layer.

FIG. 4 illustrates a crack that passes inside the insulating layer 30 and the base body 10 and fractures the at least one inner conductor 40.

In a ceramic substrate 301 in FIG. 4, the second electrode 22 has a non-conductive component content of more than 10% by weight. Therefore, the adhesion between the second electrode 22 and the insulating layer 30 is stronger than that in the ceramic substrate 1 in FIG. 3. In the case where the ceramic substrate 301 is subjected to an electrode delamination stress, the stress is concentrated on the outer periphery 22e of the second electrode 22. Thus, a crack which passes inside the insulating layer 30 is likely to occur from the outer periphery 22e of the second electrode 22. In this case, the direction of the crack growth cannot be controlled. No part exists that inhibits the growth of a crack before reaching the base body 10. Therefore, the crack may grow into the base body 10 and fracture the at least one inner conductor 40 in the base body 10, which may disrupt the electrical conductivity from the terminal electrode 20 to the at least one inner conductor 40. In FIG. 4, the crack growing from the outer periphery 22e of the second electrode 22 passes through the outer periphery 21e of the first electrode 21 and reaches the inside of the base body 10 and fractures the at least one inner conductor 40.

In the case where the non-conductive component content of the second electrode 22 is greater than the non-conductive component content of the first electrode 21, a crack passing inside the insulating layer 30 like the one in FIG. 4 is likely to occur, instead of a crack along the boundary between the second electrode 22 and the insulating layer 30 like the one in FIG. 3. Therefore, the crack may grow into the base body 10 and fracture the at least one inner conductor 40, which may disrupt the electrical conductivity from the terminal electrode 20 to the at least one inner conductor 40.

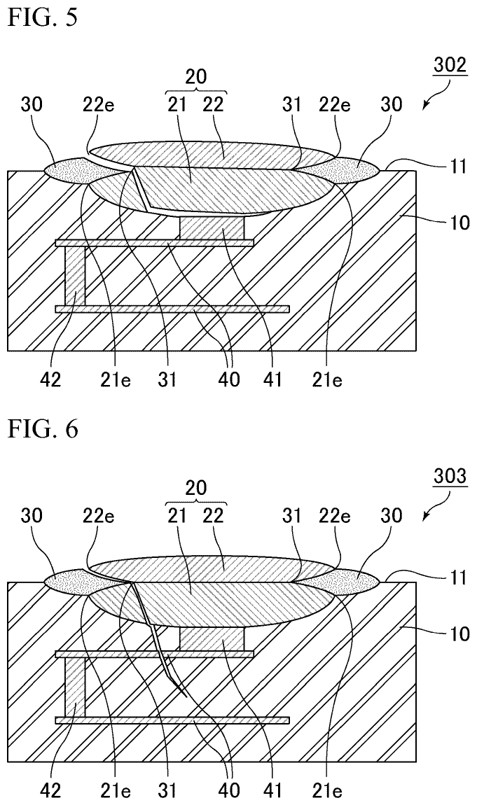

FIG. 5 is a schematic cross-sectional view showing how a crack forms in a ceramic substrate of a comparative example in which a first electrode weakly adheres to a base body.

FIG. 5 illustrates a crack that passes inside the first electrode 21 and extends between the first electrode 21 and the base body 10.

In a ceramic substrate 302 in FIG. 5, the first electrode 21 has a non-conductive component content of less than 3% by weight. Therefore, the adhesion between the first electrode 21 and the base body 10 is weaker than that in the ceramic substrate 1 in FIG. 3. In the case where the ceramic substrate 302 is subjected to an electrode delamination stress, a crack that passes inside the first electrode 21 and extends between the first electrode 21 and the base body 10 is likely to occur. This causes detachment of the first electrode 21 from the base body 10 and the via conductor 41, which may disrupt the electrical conductivity between the terminal electrode 20 and the at least one inner conductor 40.

FIG. 6 is a schematic cross-sectional view showing how a crack forms in a ceramic substrate of a comparative example in which a first electrode itself has a low strength.

FIG. 6 illustrates a crack that passes inside the first electrode 21 and the base body 10 and fractures the at least one inner conductor 40.

In a ceramic substrate 303 in FIG. 6, the non-conductive component content of the first electrode 21 is more than 40% by weight. Therefore, the first electrode 21 itself is less stronger than that in the ceramic substrate 1 in FIG. 3. In the case where the ceramic substrate 303 is subjected to an electrode delamination stress, a crack reaching the inner edge 31 of the insulating layer 30 tends to grow into the first electrode 21. The crack grows into the base body 10 and fractures the at least one inner conductor 40, which may disrupt the electrical conductivity from the terminal electrode 20 to the at least one inner conductor 40.

The first electrode 21 which has a high non-conductive component content can strongly adheres to the base body 10. On the other hand, the first electrode 21 which has a low non-conductive component content itself can have a high strength.

In view of the above, the non-conductive component content of the first electrode 21 is preferably from 5% by weight to 20% by weight.

The non-conductive component content of the first electrode 21 is more preferably from 10% by weight to 20% by weight.

The non-conductive component content of the first electrode 21 may be from 10% by weight to 15% by weight.

When the second electrode 22 has a low non-conductive component content, a crack is likely to occur along the boundary between the second electrode 22 and the insulating layer 30.

In view of the above, the non-conductive component content of the second electrode 22 is preferably from 0.5% by weight to 6% by weight.

The non-conductive component content of the second electrode 22 is more preferably from 0.5% by weight to 3% by weight.

The non-conductive component content of the first electrode 21 is preferably greater than the non-conductive component content of the second electrode 22. In this case, a crack is likely to occur along the boundary between the second electrode 22 and the insulating layer 30, whereby reliable electrical conductivity can be more sufficiently achieved from the terminal electrode 20 to the at least one inner conductor 40.

The following will specifically describe conductive components and non-conductive components contained in the first electrode 21 and the second electrode 22.

The first electrode 21 and the second electrode 22 each contain Cu or Ag as a conductive component. The first electrode 21 and the second electrode 22 may contain only one of Cu and Ag or both Cu and Ag as conductive component(s).

The first electrode 21 and the second electrode 22 may contain at least one of glass and filler as a non-conductive component.

In the case where the first electrode 21 or the second electrode 22 contains glass and filler as non-conductive components, the non-conductive component content means the sum of the glass content and the filler content.

Non-limiting examples of the glass as a non-conductive component include borosilicate glass and crystallized glass. The glass as a non-conductive component may be the same as the glass contained in the base body 10 or the glass contained in the insulating layer 30. The glass as a non-conductive component is preferably the same as the glass contained in the base body 10 and the insulating layer 30. The glass contained in the first electrode 21 or the second electrode 22 increases the adhesion between the insulating layer 30 and the first electrode 21 or the second electrode 22.

Examples of the glass as a non-conductive component include glass containing 44.0 to 69.0% by weight of RO (R represents at least one alkaline-earth metal selected from Ba, Ca, and Sr), 14.2 to 30.0% by weight of SiO₂, 10.0 to 20.0% by weight of B₂O₃, 0.5 to 4.0% by weight of Al₂O₃, 0.3 to 7.5% by weight of Li₂O, and 0.1 to 5.5% by weight of MgO.

Examples of the glass as a non-conductive component also include glass that has a SiO₂ content of from 15% by weight to 65% by weight, a B₂O₃ content of from 11% by weight to 30% by weight, a weight ratio of SiO₂ to B₂O₃ (SiO₂/B₂O₃) of 1.21 or greater, and a weight ratio of Al₂O₃ to ZnO (Al₂O₃/ZnO) of from 0.75 to 1.64.

The filler as a non-conductive component may be a ceramic, and examples thereof include ceramics such as Al₂O₃, ZrO₂, Mg₂SiO₄, and SiO₂. The filler as a non-conductive component is preferably a ceramic that has the same composition as the ceramic contained in the base body 10 and the insulating layer 30. The filler contained in the first electrode 21 or the second electrode 22 increases the adhesion between the insulating layer 30 and the first electrode 21 or the second electrode 22.

In an embodiment of the present disclosure, the non-conductive component content of each of the first electrode 21 and the second electrode 22 may be the sum of the glass content and the filler content. In this case, the non-conductive component content of each of the first electrode 21 and the second electrode 22 may be determined by measuring the glass content and the filler content of each of the first electrode 21 and the second electrode 22.

In an embodiment of the present disclosure, the non-conductive component content of each of the first electrode 21 and the second electrode 22 may be the glass content. In this case, the non-conductive component content of each of the first electrode 21 and the second electrode 22 may be determined by measuring the glass content of each of the first electrode 21 and the second electrode 22.

The glass content of the first electrode 21 may be from 0% by weight to 40% by weight, from 3% by weight to 40% by weight, from 5% by weight to 20% by weight, from 10% by weight to 20% by weight, or from 10% by weight to 15% by weight.

The first electrode 21 may contain only glass as a non-conductive component.

The filler content of the first electrode 21 may be from 0% by weight to 40% by weight, from 3% by weight to 40% by weight, from 5% by weight to 20% by weight, from 10% by weight to 20% by weight, or from 10% by weight to 15% by weight.

The first electrode 21 may contain only filler as a non-conductive component.

The sum of the glass content and the filler content in the first electrode 21 may be from 0% by weight to 40% by weight, from 3% by weight to 40% by weight, from 5% by weight to 20% by weight, from 10% by weight to 20% by weight, or from 10% by weight to 15% by weight.

The first electrode 21 may contain only glass and filler as non-conductive components.

The glass content of the second electrode 22 may be from 0% by weight to 10% by weight, from 0.5% by weight to 6% by weight, or from 0.5% by weight to 3% by weight. The second electrode 22 may contain only glass as a non-conductive component.

The filler content of the second electrode 22 may be from 0% by weight to 10% by weight, from 0.5% by weight to 6% by weight, or from 0.5% by weight to 3% by weight. The second electrode 22 may contain only filler as a non-conductive component.

The sum of the glass content and the filler content in the second electrode 22 may be from 0% by weight to 10% by weight, from 0.5% by weight to 6% by weight, or from 0.5% by weight to 3% by weight.

The second electrode 22 may contain only glass and filler as non-conductive components.

The glass content of the first electrode 21 is preferably equal to or greater than the glass content of the second electrode 22. The glass content of the first electrode 21 is more preferably greater than the glass content of the second electrode 22.

The filler content of the first electrode 21 is preferably equal to or greater than the filler content of the second electrode 22. The filler content of the first electrode 21 is more preferably greater than the filler content of the second electrode 22.

The sum of the glass content and the filler content in the first electrode 21 is preferably equal to or greater than the sum of the glass content and the filler content in the second electrode 22. The sum of the glass content and the filler content in the first electrode 21 is more preferably greater than the sum of the glass content and the filler content in the second electrode 22.

In the measurement of the glass contents and the filler contents of the first electrode 21 and the second electrode 22, glass and filler may be distinguished or separated by analyzing an electron diffraction pattern using a scanning electron microscope (SEM) or a transmission electron microscope (TEM) or by removing glass portions by dissolution with hydrofluoric acid, for example.

As described above, the non-conductive component content can be calculated from the weight percentages of elements in a cross section of an electrode measured by SEM-EDX. In this calculation method, the weight percentages of non-conductive components added upon charging the raw materials of an electrode are assumed from the weight percentages of the elements in the electrode after it is fired. Therefore, the non-conductive component content of the first electrode 21 and the non-conductive component content of the second electrode 22 may be calculated from the weight percentages of the elements upon charging the raw materials.

In the case where the percentages of the components used upon charging the raw materials to form the first electrode and the second electrode are known, the ratio of the total weight of glass and filler relative to the total weight of Cu, Ag, glass, and filler added upon charging the raw materials may be calculated and defined as the non-conductive component content.

In the case where only glass is used as a non-conductive component in the first electrode 21 or the second electrode 22, the ratio of the weight of glass relative to the total weight of Cu, Ag, and glass added upon charging the raw materials may be calculated and defined as the non-conductive component content.

Hereinafter, the relationship between the first electrode 21 and the second electrode 22 will be described with reference to FIG. 1 and FIG. 2.

In a cross-sectional view of the section where the first electrode 21, the insulating layer 30, and the second electrode 22 overlap in this order from the outer surface of the base body 10 in the thickness direction, the thickness (length indicated by double-headed arrow t1 in FIG. 1) of the first electrode 21 is preferably equal to or greater than the thickness (length indicated by double-headed arrow t2 in FIG. 1) of the second electrode 22 at the inner edge 31 of the insulating layer 30.

Such a thick first electrode 21 has greater resistance to stress at the inner edge 31 of the insulating layer 30, whereby reliable electrical conductivity can be more sufficiently achieved from the terminal electrode 20 to the at least one inner conductor 40.

In FIG. 1, the thickness (length indicated by double-headed arrow t1 in FIG. 1) of the first electrode 21 is greater than the thickness (length indicated by double-headed arrow t2 in FIG. 1) of the second electrode 22 at the inner edge 31 of the insulating layer 30. The thickness (length indicated by double-headed arrow t1 in FIG. 1) of the first electrode 21 may be the same as the thickness (length indicated by double-headed arrow t2 in FIG. 1) of the second electrode 22.

The thickness (length indicated by double-headed arrow t1 in FIG. 1) of the first electrode 21 at the inner edge 31 of the insulating layer 30 may be, for example, from 5 μm to 20 μm. The thickness (length indicated by double-headed arrow t2 in FIG. 1) of the second electrode 22 at the inner edge 31 of the insulating layer 30 may be, for example, from 5 μm to 15 μm.

The ratio (t1/t2) of the thickness of the first electrode 21 to the thickness of the second electrode 22 at the inner edge 31 of the insulating layer 30 is not limited and may be, for example, from 1.0 to 4.0, from 1.0 to 2.0, or from more than 1.0 to 2.

In a plan view in a thickness direction orthogonal to the outer surface of the base body 10, the outer periphery 21e of the first electrode 21 preferably overlaps the outer periphery 22e of the second electrode 22 or outwardly extends beyond the outer periphery 22e of the second electrode 22. Specifically, in a plan view in a thickness direction orthogonal to the outer surface of the base body 10, the entire second electrode 22 preferably overlaps the first electrode 21. In this case, concentration of stress on the outer periphery 22e of the second electrode 22 can be suppressed. This further suppresses occurrence of a crack which passes inside the insulating layer 30 and the base body 10 and fractures the at least one inner conductor 40, like the one in FIG. 4. Therefore, reliable electrical conductivity can be more sufficiently achieved from the terminal electrode 20 to the at least one inner conductor 40.

In a plan view in a thickness direction orthogonal to the outer surface of the base body 10, the area of the first electrode 21 is preferably equal to or larger than the area of the second electrode 22. In this case, concentration of stress on the outer periphery 22e of the second electrode 22 can be suppressed. This further suppresses occurrence of a crack which passes inside the insulating layer 30 and the base body 10 and fractures the at least one inner conductor 40, like the one in FIG. 4. Therefore, reliable electrical conductivity can be more sufficiently achieved from the terminal electrode 20 to the at least one inner conductor 40.

In a plan view of the ceramic substrate 1 in a thickness direction orthogonal to the outer surface of the base body 10 in FIG. 1 or FIG. 2, the outer periphery 21e of the first electrode 21 overlaps the outer periphery 22e of the second electrode 22. Moreover, in a plan view in a thickness direction orthogonal to the outer surface of the base body 10, the area of the first electrode 21 is equal to the area of the second electrode 22.

The width (length indicated by double-headed arrow w1 in FIG. 1) is not limited for the section where the first electrode 21, the insulating layer 30, and the second electrode 22 overlap in this order from the outer surface of the base body 10, in a thickness direction orthogonal to the outer surface of the base body 10. For example, the width may be from 10 μm to 75 μm. When the width of the section where the first electrode 21, the insulating layer 30, and the second electrode 22 overlap in this order is 10 μm or more, the insulating layer 30 can sufficiently improve the adhesion between the terminal electrode 20 and the base body 10. On the other hand, when the section where the first electrode 21, the insulating layer 30, and the second electrode 22 overlap in this order is narrow, the distance from the edge of the substrate to an electrode or between electrodes can be increased. Additionally, the contact area of the first electrode 21 and the second electrode 22 is large, so that the adhesion of the first electrode 21 to the second electrode 22 can be strengthened. In view of the above, the width of the section where the first electrode 21, the insulating layer 30, and the second electrode 22 overlap in this order may be, for example, 75 μm or less. The width of the section where the first electrode 21, the insulating layer 30, and the second electrode 22 overlap in this order may also be from 20 μm to 40 μm. In a plan view in a thickness direction orthogonal to the outer surface of the base body 10, the width of the section where the first electrode 21, the insulating layer 30, and the second electrode 22 overlap in this order may be constant. Moreover, in a plan view in a thickness direction orthogonal to the outer surface of the base body 10, the section where the first electrode 21, the insulating layer 30, and the second electrode 22 overlap in this order may have a different width at one or more side(s) of the electrodes.

In FIG. 1, the width of a portion where the insulating layer 30 covers the first electrode 21 is equal to the width of the section where the first electrode 21, the insulating layer 30, and the second electrode 22 overlap in this order. The portion where the insulating layer 30 covers the first electrode 21 may be wider than the section where the first electrode 21, the insulating layer 30, and the second electrode 22 overlap in this order. The width of the portion where the insulating layer 30 covers the first electrode 21 may be from 10 μm to 75 μm or may be from 20 μm to 40 μm.

In FIG. 1, the first electrode 21 is inside a plane including an outer surface 11 of the base body 10 which is a portion of the outer surface of the base body 10 and is a part without the terminal electrode 20 and the insulating layer 30 (the first electrode 21 is in the lower part of FIG. 1). The first electrode 21 may extend along the plane including the outer surface 11 of the base body 10 which is a portion of the outer surface of the base body 10 and is a part without the terminal electrode 20 and the insulating layer 30. Moreover, the first electrode 21 may be outside the plane including the outer surface 11 of the base body 10 which is a portion of the outer surface of the base body 10 and is a part without the terminal electrode 20 and the insulating layer 30 (the first electrode 21 may be in the upper part of FIG. 1).

In FIG. 1, the outer surface of the second electrode 22 and the outer surface of the insulating layer 30 are outside the outer surface of the base body 10 (the outer surfaces are in the upper part of FIG. 1). The outer surface 11 of the base body 10 which is a portion of the outer surface of the base body 10 and is a part without the terminal electrode 20 and the insulating layer 30, the outer surface of the second electrode 22, and the outer surface of the insulating layer 30 may be flush. Moreover, the second electrode 22 and the insulating layer 30 may be inside the outer surface 11 of the base body 10 which is a portion of the outer surface of the base body 10 and is a part without the terminal electrode 20 and the insulating layer 30 (the second electrode 22 and the insulating layer 30 may be in the lower part of FIG. 1).

Next, an example of a method for producing the ceramic substrate of the present disclosure will be described with reference to an exemplary method for producing an electronic component (LC filter) in which the inner conductors in the base body of the ceramic substrate serve as an inductance element and a capacitance element.

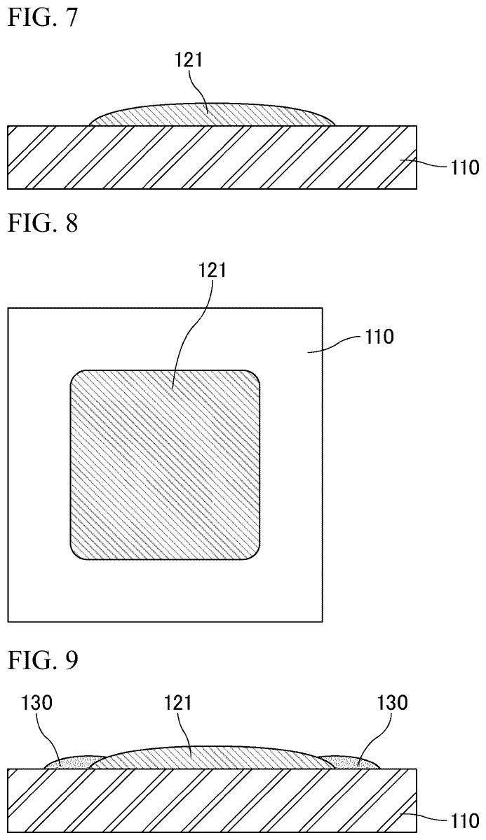

FIG. 7 is a schematic cross-sectional view showing a process of forming a first electrically conductive paste layer to be fired into a first electrode. FIG. 8 is a schematic plan view showing the process of forming a first electrically conductive paste layer to be fired into a first electrode.

Although no inner conductor is shown in FIG. 7 to FIG. 17 to simplify the explanation of the ceramic substrate, the base body includes at least one inner conductor therein.

First, a plurality of ceramic green sheets 110 are prepared. The ceramic green sheets 110 will become ceramic layers of the base body 10 after they are fired.

The ceramic green sheets 110 have been formed by, for example, molding a slurry containing ceramic powder, an organic binder, and a solvent into sheets by a doctor blading method or other methods. The slurry may contain various additives such as a dispersant and a plasticizer. Examples of the materials of the ceramic green sheets 110 include materials described as the materials of the base body 10 in the description of the ceramic substrate.

A first electrically conductive paste layer 121 to be fired into the first electrode 21 is formed on the ceramic green sheets 110, which is to be laminated and disposed on a surface of the electronic component. The formation of the first electrically conductive paste layer 121 includes patterning by a technique such as screen printing or photolithography.

The area where the first electrically conductive paste layer 121 is formed may be appropriately determined depending on the distance between electrodes or the distance from the electrode to the edge of the electronic component, for example.

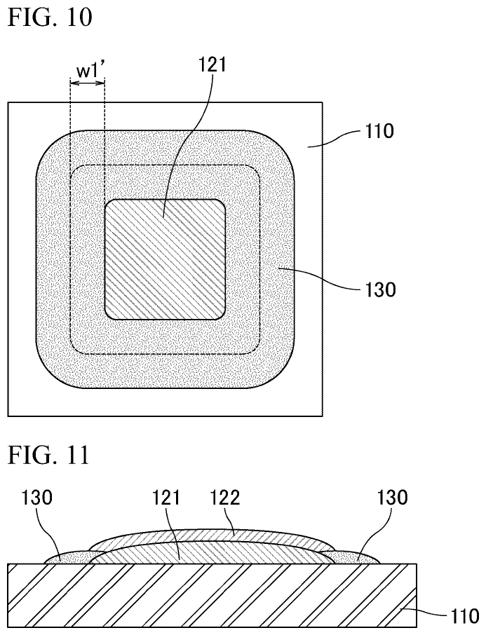

FIG. 9 is a schematic cross-sectional view showing a process of forming an insulating paste layer to be fired into an insulating layer. FIG. 10 is a schematic plan view showing the process of forming an insulating paste layer to be fired into an insulating layer.

An insulating paste layer 130 to be fired into the insulating layer 30 is formed on an outer periphery of the first electrically conductive paste layer 121. The insulating paste layer 130 is formed to continuously extend on a part of the ceramic green sheet 110 where the first electrically conductive paste layer 121 is not formed. The formation of the insulating paste layer 130 includes patterning by a technique such as screen printing.

The width (width indicated by double-headed arrow w1′ in FIG. 10) of a part where the insulating paste layer 130 overlaps the first electrically conductive paste layer 121 may be appropriately determined. When the part where the insulating paste layer 130 overlaps the first electrically conductive paste layer 121 is wide, the insulating layer 30 after firing can sufficiently improve the adhesion between the first electrode 21 and the base body 10. When the part where the insulating paste layer 130 overlaps the first electrically conductive paste layer 121 is narrow, the contact area of the first electrically conductive paste layer 121 and a second electrically conductive paste layer 122, which will be described later, increases, so that the adhesion after firing between the first electrode 21 and the second electrode 22 can be strengthened. In view of the above, the width of the part where the insulating paste layer 130 overlaps the first electrically conductive paste layer 121 may be from 10 μm to 75 μm or from 20 μm to 40 μm.

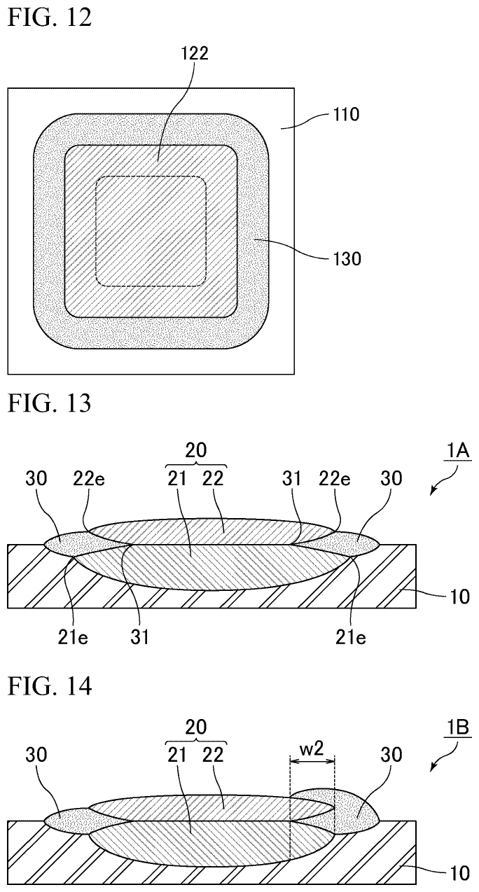

FIG. 11 is a schematic cross-sectional view showing a process of forming a second electrically conductive paste layer to be fired into a second electrode. FIG. 12 is a schematic plan view showing the process of forming a second electrically conductive paste layer to be fired into a second electrode.

A second electrically conductive paste layer 122 to be fired into the second electrode 22 is formed on the first electrically conductive paste layer 121 and the insulating paste layer 130. The second electrically conductive paste layer 122 is formed to cover the entirety of the exposed part of the first electrically conductive paste layer 121. Moreover, the second electrically conductive paste layer 122 is formed to cover a portion of the exposed part of the insulating paste layer 130.

The area where the second electrically conductive paste layer 122 is formed is appropriately determined depending on the product specifications or the like. The area where the second electrically conductive paste layer 122 is formed is preferably equal to or smaller than the area where the first electrically conductive paste layer 121 is formed. Separately, a hole for a via conductor is formed in specific ceramic green sheets 110. The hole may be formed by, for example, laser processing. A conductive paste layer to be fired into an inner conductor is formed by applying a conductive paste in a desired shape to the surface of each specific ceramic green sheet 110. The conductive paste layer can be formed by screen printing or other techniques using, for example, a conductive paste containing Cu or Ag as a conductive component. The conductive paste is charged into the hole for a via conductor to form a conductive paste body to be fired into a via conductor. Accordingly, an electrode to be an inductance element or a capacitance element in an LC filter can be formed.

Subsequently, the plurality of ceramic green sheets 110 are laminated to obtain an unfired laminate.

The obtained unfired laminate is pressed, for example, at a pressure of from 100 MPa to 200 MPa and at a temperature of from 50° C. to 80° C. The pressing pushes the first electrically conductive paste layer 121, the second electrically conductive paste layer 122, and the insulating paste layer 130 to the unfired laminate. As shown in FIG. 1, through this process, the first electrode 21 may be disposed inside a plane including the outer surface 11 of the base body 10 which is a portion of the outer surface of the base body 10 and is a part without the terminal electrode 20 and the insulating layer 30 in the fired ceramic substrate 1. Moreover, the pressing may be performed such that the second electrically conductive paste layer 122, the insulating paste layer 130, and the outer surface of the unfired laminate become flush, whereby the outer surface 11 of the base body 10 which is a portion of the outer surface of the base body 10 and is a part without the terminal electrode 20 and the insulating layer 30, the outer surface of the second electrode 22, and the outer surface of the insulating layer 30 become flush in the fired ceramic substrate 1.

If necessary, the unfired laminate may be singulated into chips by cutting the unfired laminate using a dicer, a micro cutter, or other cutters.

The surface of the unfired laminate may be polished by barrel finishing. The polishing is performed by enclosing the unfired laminate into a small container called a barrel together with media balls which are harder than the material of the base body 10 and rotating the barrel. The barrel finishing rounds the corner portions and ridge portions of the unfired laminate.

Thereafter, the unfired laminate is fired to obtain an electronic component including the ceramic substrate of the present disclosure. The firing temperature is not limited and is preferably, for example, from 800° C. to 1000° C. Non-limiting examples of the firing atmosphere include nitrogen atmosphere. The firing atmosphere may be air when an oxidation-resistant electrode material is used.

In the above production method, the first electrically conductive paste layer 121, the second electrically conductive paste layer 122, and the insulating paste layer 130 are simultaneously fired. The firing may be performed in a state where only the first electrically conductive paste layer 121 and the insulating paste layer 130 are formed (as in a state shown in FIG. 9 and FIG. 10). In this case, the second electrode 22 may be formed by the second electrically conductive paste layer 122 to cover the fired first electrode 21 and then subjected to thermal treatment for baking.

FIG. 13 is a schematic cross-sectional view showing a first modification example of the ceramic substrate.

In a ceramic substrate 1A in a plan view in a thickness direction orthogonal to the outer surface of the base body 10 in FIG. 13, the outer periphery 21e of the first electrode 21 is outside the outer periphery 22e of the second electrode 22. In the ceramic substrate 1A in a view in the thickness direction, the area of the first electrode 21 is larger than the area of the second electrode 22.

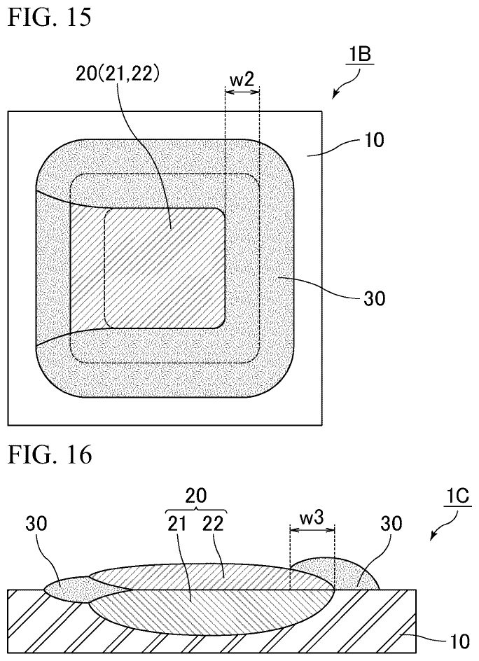

FIG. 14 is a schematic cross-sectional view showing a second modification example of the ceramic substrate. FIG. 15 is a schematic plan view showing the second modification example of the ceramic substrate.

In a ceramic substrate 1B in FIG. 14 and FIG. 15, the insulating layer 30 partly covers the outer surface of the second electrode 22. In a thickness direction (the vertical direction in FIG. 14) orthogonal to the outer surface of the base body 10 in FIG. 14, a section (the section indicated by double-headed arrow w2 in FIG. 14) is present where the first electrode 21, the insulating layer 30, the second electrode 22, and the insulating layer 30 overlap in this order from the outer surface of the base body 10. In the section where the first electrode 21, the insulating layer 30, the second electrode 22, and the insulating layer 30 overlap in this order from the outer surface of the base body 10, a portion of the insulating layer 30 is interposed between the first electrode 21 and the second electrode 22 and also a portion of the insulating layer 30 covers the outer surface of the second electrode 22.

In FIG. 14, the width (the length indicated by double-headed arrow w2 in FIG. 14) of the portion of the insulating layer 30 covering the outer surface of the second electrode 22 is equal to the width of the section where the first electrode 21, the insulating layer 30, and the second electrode 22 overlap in this order from the outer surface of the base body 10.

In FIG. 14, the width (the length indicated by double-headed arrow w2 in FIG. 14) of the portion of the insulating layer 30 covering the outer surface of the second electrode 22 may be larger or smaller than the width of the section where the first electrode 21, the insulating layer 30, and the second electrode 22 overlap in this order from the outer surface of the base body 10.

As shown in FIG. 15, the section where the first electrode 21, the insulating layer 30, the second electrode 22, and the insulating layer 30 overlap in this order from the outer surface of the base body 10 may be present at three sides of the terminal electrode 20. The section where the first electrode 21, the insulating layer 30, the second electrode 22, and the insulating layer 30 overlap in this order from the outer surface of the base body 10 may be present at all sides of the terminal electrode 20.

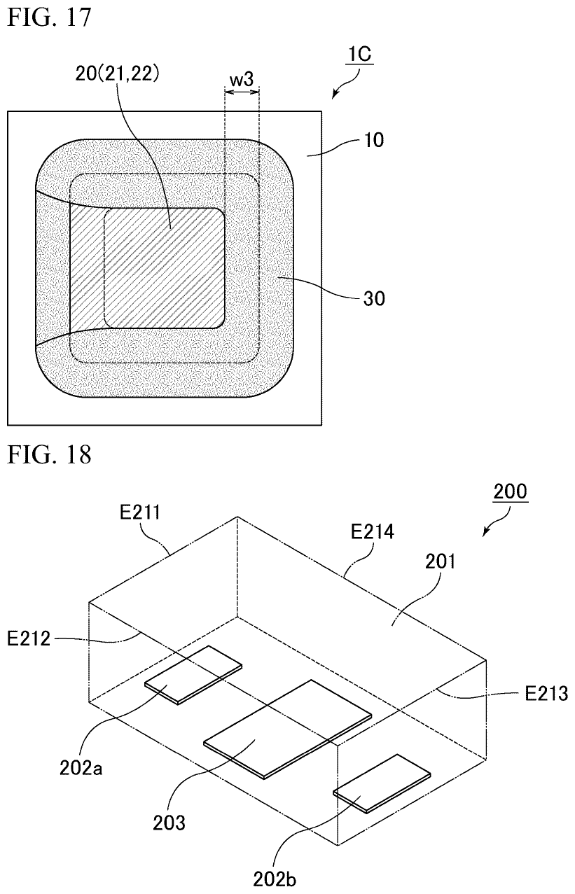

FIG. 16 is a schematic cross-sectional view showing a third modification example of the ceramic substrate. FIG. 17 is a schematic plan view showing the third modification example of the ceramic substrate.

In a ceramic substrate 1C in FIG. 16 and FIG. 17, the insulating layer 30 partly covers the outer surface of the second electrode 22. In a thickness direction (the vertical direction in FIG. 16) orthogonal to the outer surface of the base body 10 in FIG. 16, a section (the section indicated by double-headed arrow w3 in FIG. 16) is present where the first electrode 21, the second electrode 22, and the insulating layer 30 overlap in this order from the outer surface of the base body 10. In the section where the first electrode 21, the second electrode 22, and the insulating layer 30 overlap in this order from the outer surface of the base body 10, the insulating layer 30 is not interposed between the first electrode 21 and the second electrode 22.

As shown in FIG. 17, the section where the first electrode 21, the second electrode 22, and the insulating layer 30 overlap in this order from the outer surface of the base body 10 may be present at three sides of the terminal electrode 20.

The electronic component of the present disclosure will be described below.

The electronic component of the present disclosure includes the ceramic substrate of the present disclosure.

The electronic component is not limited and may be an electronic component in which the inner conductor in the base body of the ceramic substrate serves as an electronic component element such as an inductance element or a capacitance element. The electronic component may also be an LC filter in which the inner conductors in the base body of the ceramic substrate serve as an inductance element and a capacitance element.

Alternatively, the electronic component may be an electronic component that includes the ceramic substrate containing a chip component or the ceramic substrate with a chip component mounted on its surface.

An example of the electronic component of the present disclosure will be described with reference to an exemplary LC filter in which the inner conductors in the base body of the ceramic substrate serve as an inductance element and a capacitance element.

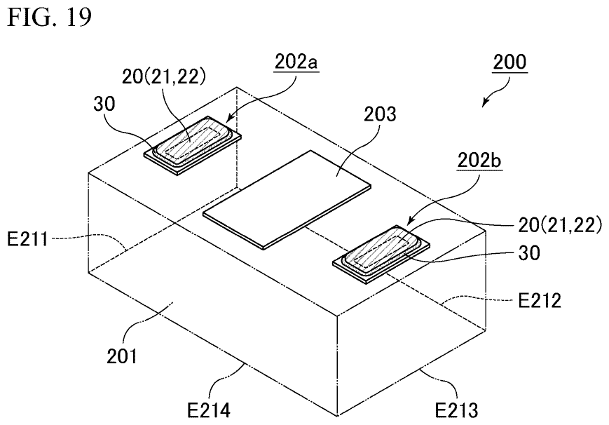

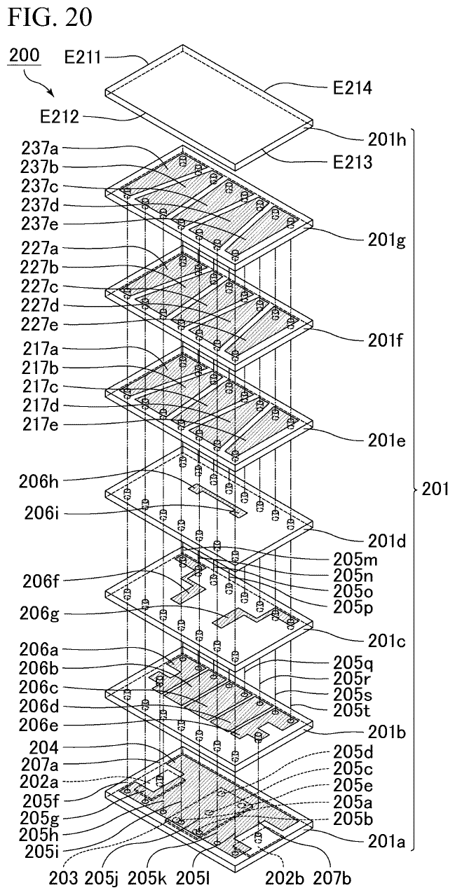

FIG. 18 is a schematic perspective view showing an example of the electronic component of the present disclosure. FIG. 19 is a schematic perspective view showing an input/output terminal and a ground terminal in an example of the electronic component of the present disclosure. FIG. 20 is an exploded schematic perspective view showing an example of the electronic component of the present disclosure.

A laminated LC filter 200 includes a base body 201.

As shown in FIG. 18, an input/output terminal 202a, an input/output terminal 202b, and a ground terminal 203 are disposed on the lower main surface of the base body 201. As shown in FIG. 19, the input/output terminals 202a and 202b each include a terminal electrode 20 and an insulating layer 30. Although FIG. 19 does not show details of the terminal electrode 20 and the insulating layer 30, the structures of the terminal electrode 20 and the insulating layer 30 are the same as the structures of the terminal electrode 20 and the insulating layer 30 in the ceramic substrate 1, respectively, shown in FIG. 1, FIG. 2, and FIG. 3. Although the ground terminal 203 in FIG. 19 does not include the terminal electrode 20 and the insulating layer 30, the ground terminal 203 may include the terminal electrode 20 and the insulating layer 30. In the case of the ground terminal 203 including the terminal electrode 20 and the insulating layer 30, the structures of the terminal electrode 20 and the insulating layer 30 may be the same as the structures of the terminal electrode 20 and the insulating layer 30 in the ceramic substrate 1, respectively, shown in FIG. 1, FIG. 2, and FIG. 3.

As shown in FIG. 20, the base body 201 is a laminate of eight dielectric layers 201a to 201h made of a material such as a ceramic, which are laminated in order from the bottom up.

As shown in FIG. 18, FIG. 19, and FIG. 20, the base body 201 has a first side E211, a second side E212, a third side E213, and a fourth side E214 which are sequentially connected when viewed in the lamination direction of the dielectric layers 201a to 201h.

First, the dielectric layers 201a to 201h constituting the base body 201 will be individually described.

The input/output terminal 202a, the input/output terminal 202b, and the ground terminal 203 are disposed on the lower main surface of the dielectric layer 201a.

The dielectric layer 201a includes five via conductors 205a to 205e which penetrate from the upper main surface to the lower main surface of the dielectric layer 201a.

A ground conductor pattern 204 is formed on the upper main surface of the dielectric layer 201a. The ground conductor pattern 204 is connected to the ground terminal 203 through the via conductors 205a to 205e.

The dielectric layer 201b includes seven via conductors 205f to 205l which penetrate from the upper main surface to the lower main surface of the dielectric layer 201b. In the exploded perspective view of FIG. 20, the via conductors 205f to 205l are each depicted as being extended downward more than the actual position to illustrate the connection relationship (the same applies to via conductors described below). The via conductors 205f to 205l are each connected to the ground conductor pattern 204.

Five capacitor conductor patterns 206a to 206e are formed on the upper main surface of the dielectric layer 201b. The capacitor conductor pattern 206a is connected to the input/output terminal 202a through the via conductor 207a. The capacitor conductor pattern 206e is connected to the input/output terminal 202b through the via conductor 207b.

The via conductor 207a and the via conductor 207b each correspond to the via conductor 41 connected to the first electrode 21 in FIG. 1.

The dielectric layer 201c includes seven via conductors 205f to 205l which penetrate from the upper main surface to the lower main surface of the dielectric layer 201c. The via conductors 205f to 205l are also formed through the dielectric layer 201b as described above. Here, via conductors with the same reference sign formed in different dielectric layers are defined as being connected to each other. The dielectric layer 201c includes eight different via conductors 205m to 205t which penetrate from the upper main surface to the lower main surface of the dielectric layer 201c. The via conductors 205m and 205n are each connected to the capacitor conductor pattern 206a. The via conductor 2050 is connected to the capacitor conductor pattern 206b. The via conductors 205p and 205q are each connected to the capacitor conductor pattern 206c. The via conductor 205r is connected to the capacitor conductor pattern 206d. The via conductors 205s and 205t are each connected to the capacitor conductor pattern 206e.

Two capacitor conductor patterns 206f and 206g are formed on the upper main surface of the dielectric layer 201c. The capacitor conductor pattern 206f is connected to the via conductors 205m and 205n. The capacitor conductor pattern 206g is connected to the via conductors 205s and 205t.

The dielectric layer 201d includes seven via conductors 205f to 205l and eight via conductors 205m to 205t which penetrate from the upper main surface to the lower main surface of the dielectric layer 201d.

Two capacitor conductor patterns 206h and 206i are formed on the upper main surface of the dielectric layer 201d. The capacitor conductor pattern 206h and the capacitor conductor pattern 206i are interconnected.

The dielectric layer 201e includes seven via conductors 205f to 205l and eight via conductors 205m to 205t which penetrate from the upper main surface to the lower main surface of the dielectric layer 201e.

Five linear conductor patterns 217a to 217e are formed on the upper main surface of the dielectric layer 201e. The linear conductor patterns 217a to 217e are each disposed to extend in the same direction as the extending direction of the first side E211 and the third side E213 facing to each other. The linear conductor patterns 217a to 217e are each formed such that the opposing long sides thereof are not parallel to each other. Thus, the linear conductor patterns 217a to 217e each have at least one side that is not parallel to any of the first side E211, the second side E212, the third side E213, and the fourth side E214 of the base body 201.

One via conductor 205f is connected to the linear conductor pattern 217a at an area near the edge closer to the second side E212, and two via conductors 205m and 205n are connected the linear conductor pattern 217a at an area near the edge closer to the fourth side E214. Two via conductors 205g and 205h are connected the linear conductor pattern 217b at an area near the edge closer to the second side E212, and one via conductor 2050 is connected to the linear conductor pattern 217b at an area near the edge closer to the fourth side E214. One via conductor 205i is connected to the linear conductor pattern 217c at an area near the edge closer to the second side E212, and two via conductors 205p and 205q are connected to the linear conductor pattern 217c at an area near the edge closer to the fourth side E214. Two via conductors 205j and 205k are connected to the linear conductor pattern 217d at an area near the edge closer to the second side E212, and one via conductor 205r is connected to the linear conductor pattern 217d at an area near the edge closer to the fourth side E214. One via conductor 205l is connected to the linear conductor pattern 217e at an area near the edge closer to the second side E212, and two via conductors 205s and 205t are connected to the linear conductor pattern 217e at an area near the edge closer to the fourth side E214.

As described above, the linear conductor patterns 217a to 217e are each connected to the total seven via conductors 205f to 205l at an area near the edge closer to the second side E212, with a sequence of increase and decrease in the number of the via conductors, specifically, one, two, one, two, and one, and also connected to the total eight via conductors 205m to 205t at an area near the edge closer to the fourth side E214, with a sequence of increase and decrease in the number of the via conductors, specifically, two, one, two, one, and two. In other words, the laminated LC filter 200 is configured to connect as many via conductors as possible, i.e., the via conductors 205f to 205t, to each of the linear conductor patterns 217a to 217e by making the most effective use of space, thereby reducing the internal resistance.

The dielectric layer 201f includes seven via conductors 205f to 205l and eight via conductors 205m to 205t which penetrate from the upper main surface to the lower main surface of the dielectric layer 201f.

Five linear conductor patterns 227a to 227e are formed on the upper main surface of the dielectric layer 201f. The shapes of the linear conductor patterns 227a to 227e are the same as the shapes of the linear conductor patterns 217a to 217e on the upper main surface of the dielectric layer 201e, respectively. The linear conductor patterns 227a to 227e are connected to the via conductors 205f to 205t at the same positions as the linear conductor patterns 217a to 217e, respectively.

The dielectric layer 201g includes seven via conductors 205f to 205l and eight via conductors 205m to 205t which penetrate from the upper main surface to the lower main surface of the dielectric layer 201g.

Five linear conductor patterns 237a to 237e are formed on the upper main surface of the dielectric layer 201g. The shapes of the linear conductor patterns 237a to 237e are the same as the shapes of the linear conductor patterns 217a to 217e on the upper main surface of the dielectric layer 201e, respectively. The linear conductor patterns 237a to 237e are each connected to the via conductors 205f to 205t at the same positions as the linear conductor patterns 217a to 217e, respectively.

The dielectric layer 201h is a protective layer.

The laminated LC filter 200 with the above-described structure can be produced using materials and production methods which have been widely used in the production of laminated LC filters.

### Examples

The following will describe examples more specifically disclosing the ceramic substrate and the electronic component of the present disclosure. The present disclosure is not limited to the examples.

LC filters of sample Nos. 1 to 22 were produced according to the method for producing an electronic component (LC filter) described with reference to FIG. 7 to FIG. 12 in the present specification. In the LC filters of sample Nos. 1 to 22, inner conductors each serving as an inductance element or a capacitance element were formed in a base body. Each sample was prepared using materials of a first electrically conductive paste layer and materials of a second electrically conductive paste layer which would satisfy the non-conductive component contents of a first electrode and a second electrode indicated in Table 2. The non-conductive component used was RO (R represents at least one alkaline-earth metal selected from Ba, Ca, and Sr)—SiO₂—B₂O₃—Al₂O₃—Li₂O—MgO-based glass.

The LC filter of Sample No. 19 was produced without forming a second electrically conductive paste layer in the production process. The LC filter of Sample No. 19 includes no second electrode. The LC filter of Sample No. 20 was produced without forming a second electrically conductive paste layer and an insulating paste layer in the production process. The LC filter of Sample No. 20 includes no second electrode and no insulating layer. The LC filters of sample Nos. 1 to 22 were produced under the same conditions excluding the above conditions. The samples No. 1, No. 2, No. 5, No. 9, No. 13, No. 14, and Nos. 17 to 21 marked with * in Table 2 are electronic components (LC filters) of comparative examples which differ from the electronic component (LC filter) including the ceramic substrate of the present disclosure.

### [Measurement of Non-Metal Content]

A cross section of each of the first electrode and the second electrode was observed by SEM-EDX. The total of the weight percentages of the elements detected by SEM-EDX excluding C and O was determined to be a total weight (100% by weight). The non-conductive component content was calculated by subtracting the weight percentages of Cu elements and Ag elements from the total weight.

### [Plating Adhesion]

Plating was performed on the top face of the second electrode. When 90% or more of the area of the second electrode had the plating, the plating adhesion was rated “◯”. Poor plating adhesion with the plated area of less than 90% was rated “x”.

### [Electrical Conductivity]

The samples after the plating with the plating adhesion rated “◯” were each subjected to solder reflow at about 240° C. to be mounted on a printed circuit board which was usable for conductivity analysis of a product, followed by flux clearing. Each sample was subjected to a thermal shock test within a temperature range of from −55° C. to 125° C. while monitoring the electrical conductivity between the terminal electrode and the inner conductors in the sample, and the number of cycles of disruption of the electrical conductivity (the number of fracture cycles) was measured. The increase or decrease in the number of fracture cycles relative to the number of fracture cycles of the sample No. 19 was evaluated using the following criteria.
◯◯: The electrical conductivity was maintained even at 150% of the number of cycles.
◯: The electrical conductivity was disrupted at 120% or more and less than 150% of the number of cycles.
x: The electrical conductivity was disrupted at less than 120% of the number of cycles.

### [Breakage Mode]

The samples which had experienced the disruption of electrical conductivity in the thermal shock test within a temperature range of from −55° C. to 125° C. were subjected to polishing of cross sections to analyze the growth of a crack, thereby identifying the site where the electrical conductivity was disrupted. The crack growth behaviors in the breakage mode in the table are as follows.

Cracking of base body: A crack that passed inside the insulating layer and the base body and fractured the inner conductor occurred as shown in FIG. 4.

Electrode delamination: A crack that passed inside the first electrode and extended between the first electrode and the base body occurred as shown in FIG. 5.

Fracture in electrode: A crack that passed inside the first electrode and the base body and fractured the inner conductor occurred as shown in FIG. 6.

TABLE 2

| | Non-conductive | | | Thermal | |
|---|---|---|---|---|---|
| | component (wt %) | | | shock resistance | |
| Sample | First | Second | Plating | Electrical | Breakage |
| No. | electrode | electrode | adhesion | conductivity | mode |
| * 1 | 2.5 | 2.5 | ∘ | x | Electrode |
| | | | | | delamination |
| * 2 | 2.5 | 5 | ∘ | x | Electrode |
| | | | | | delamination |
| 3 | 5 | 0.5 | ∘ | ∘ | Fracture in |
| | | | | | electrode |
| 4 | 5 | 5 | ∘ | ∘ | Fracture in |
| | | | | | electrode |
| * 5 | 5 | 10 | ∘ | x | Cracking of |
| | | | | | base body |
| 6 | 10 | 0.5 | ∘ | ∘∘ | — |
| 7 | 10 | 5 | ∘ | ∘∘ | — |
| 8 | 10 | 10 | ∘ | ∘∘ | — |
| * 9 | 10 | 13 | x | — | — |
| 10 | 20 | 0.5 | ∘ | ∘∘ | — |
| 11 | 20 | 5 | ∘ | ∘∘ | — |
| 12 | 20 | 10 | ∘ | ∘∘ | — |
| * 13 | 20 | 12 | ∘ | x | Cracking of |
| | | | | | base body |
| * 14 | 20 | 15 | x | — | — |
| 15 | 40 | 5 | ∘ | ∘ | Fracture in |
| | | | | | electrode |
| 16 | 40 | 10 | ∘ | ∘ | Fracture in |
| | | | | | electrode |
| * 17 | 40 | 12 | ∘ | x | Cracking of |
| | | | | | base body |
| * 18 | 50 | 5 | ∘ | x | Fracture in |
| | | | | | electrode |
| * 19 | 10 | None | ∘ | 100% | Fracture in |
| | | | | | electrode |
| * 20 | 10 | None | ∘ | x | Cracking of |
| | | | | | base body |
| * 21 | 0.5 | 0.5 | ∘ | x | Electrode |
| | | | | | delamination |
| 22 | 3 | 0.5 | ∘ | ∘ | Fracture in |
| | | | | | electrode |

As shown in Table 2, the electrical conductivity of the electronic components of the present disclosure (LC filter) was evaluated as “◯” or “◯◯”, demonstrating that reliable electrical conductivity was achieved from the terminal electrode to the inner conductor.

### REFERENCE SIGNS LIST

1, 1A, 1B, 1C, 301, 302, 303 ceramic substrate
10, 201 base body
11 part of outer surface of base body without terminal electrode and insulating layer
20 terminal electrode
20e outer periphery of terminal electrode
21 first electrode
21e outer periphery of first electrode
22 second electrode
22e outer periphery of second electrode
30 insulating layer
31 inner edge of insulating layer
40 inner conductor
41, 42, 205a to 205t, 207a, 207b via conductor
110 ceramic green sheet
121 first electrically conductive paste layer
122 second electrically conductive paste layer
130 insulating paste layer
200 laminated LC filter
201a to 201h dielectric layer
E211 first side
E212 second side
E213 third side
E214 fourth side
202a, 202b input/output terminal
203 ground terminal
204 ground conductor pattern
206a to 206i capacitor conductor pattern
217a to 217e, 227a to 227e, 237a to 237e linear conductor pattern

1. A ceramic substrate, comprising:
a base body including a ceramic layer;
at least one inner conductor in the base body;
a terminal electrode including a first electrode in contact with an outer surface of the base body and a second electrode covering a surface of the first electrode, the terminal electrode being electrically connected to the at least one inner conductor; and
an insulating layer covering at least a portion of an outer periphery of the first electrode and a portion of the outer surface of the base body,
the ceramic substrate including a section where the first electrode, the insulating layer, and the second electrode overlap in this order from the outer surface of the base body in a thickness direction orthogonal to the outer surface of the base body,
the first electrode having a non-conductive component content of from 3% by weight to 40% by weight,
the second electrode having a non-conductive component content of from 0% by weight to 10% by weight, and
the non-conductive component content of the first electrode being equal to or greater than the non-conductive component content of the second electrode.

2. The ceramic substrate according to claim 1, wherein the non-conductive component content of the first electrode is from 10% by weight to 20% by weight.

3. The ceramic substrate according to claim 2, wherein the non-conductive component content of the second electrode is from 0.5% by weight to 6% by weight.

4. The ceramic substrate according to claim 1, wherein the non-conductive component content of the second electrode is from 0.5% by weight to 6% by weight.

5. The ceramic substrate according to claim 1,
wherein, in a cross-sectional view of the section where the first electrode, the insulating layer, and the second electrode overlap in this order from the outer surface of the base body in the thickness direction,
a thickness of the first electrode is equal to or greater than a thickness of the second electrode at an inner edge of the insulating layer.

6. The ceramic substrate according to claim 5, wherein the thickness of the first electrode at the inner edge of the insulating layer is 5 μm to 20 μm.

7. The ceramic substrate according to claim 6, wherein the thickness of the second electrode at the inner edge of the insulating layer is 5 μm to 15 μm.

8. The ceramic substrate according to claim 5, wherein the thickness of the second electrode at the inner edge of the insulating layer is 5 μm to 15 μm.

9. The ceramic substrate according to claim 6, wherein a ratio of the thickness of the first electrode to the thickness of the second electrode at the inner edge of the insulating layer is from 1.0 to 4.0.

10. The ceramic substrate according to claim 1, wherein, in a plan view from the thickness direction, an area of the first electrode is equal to or larger than an area of the second electrode.

11. The ceramic substrate according to claim 1, wherein, in a plan view from the thickness direction, an outer periphery of the first electrode overlaps an outer periphery of the second electrode or outwardly extends beyond the outer periphery of the second electrode.

12. The ceramic substrate according to claim 1, wherein the at least one inner conductor includes a via conductor connected to the first electrode.

13. The ceramic substrate according to claim 1, wherein a width of the section where the first electrode, the insulating layer, and the second electrode overlap is 10 μm to 75 μm.

14. The ceramic substrate according to claim 1, wherein the insulating layer at least partly covers an outer surface of the second electrode.

15. The ceramic substrate according to claim 1, wherein the insulating layer covers an entirety of the outer periphery of the first electrode.

16. An electronic component comprising the ceramic substrate according to claim 1.
